(19) United States
(12) Patent Application Publication
(10) Pub. No.: US 2016/0054414 A1
(43) Pub. Date: Feb. 25, 2016

(54) MAGNETIC RESONANCE TOMOGRAPHY SYSTEM

(71) Applicant: Siemens Aktiengesellschaft, Muenchen (DE)

(72) Inventors: Sultan Haider, Erlangen (DE); Bjoern Heismann, Erlangen (DE)

(73) Assignee: Siemens Aktiengesellschaft, Muenchen (DE)

(21) Appl. No.: 14/832,136

(22) Filed: Aug. 21, 2015

(30) Foreign Application Priority Data
Aug. 21, 2014 (DE) 102014216669.1

(51) Int. Cl. G01R 33/54

(52) U.S. Cl. CPC G01R 33/543; G01R 33/546

(57) ABSTRACT

A magnetic resonance tomography system has a magnetic resonance scanner for performing a magnetic resonance examination, and a portable control processor having a first, wireless data interface for receiving control data for the magnetic resonance scanner from a data network, and a second, wireless data interface for transferring the control data to the magnetic resonance scanner.

### BACKGROUND OF THE INVENTION

1. Field of the Invention

The present invention concerns a magnetic resonance tomography system with a magnetic resonance scanner for performing a magnetic resonance examination on a patient.

2. Description of the Prior Art

U.S. Pat. No. 7,685,991 B2 discloses a system for making available and capturing clinical knowledge using a central server. It supplies hanging protocols, best clinical protocols, user interfaces, sequences and post-processing software using a central knowledge server.

### SUMMARY OF THE INVENTION

An object of the invention is to provide a magnetic resonance tomography system, wherein the control of the system can be adapted in a simple manner.

According to a first aspect of the invention, this object is achieved by a magnetic resonance tomography system, with a magnetic resonance scanner for performing a magnetic resonance examination, and a portable control device, that has a first, wireless data interface for receiving control data for the magnetic resonance scanner from a data network, and a second, wireless data interface for transferring the control data to the magnetic resonance scanner. The control data are data that serve to control the magnetic resonance scanner, for example, sequence data of a magnetic resonance sequence, activation data for enabling a pre-installed function of the magnetic resonance tomography device, data of a control application for controlling the magnetic resonance tomography device or data defining the post-processing of generated examination data. The magnetic resonance scanner according to the invention has the technical advantage, for example, that a user can use the mobile control device to perform a control operation on the magnetic resonance scanner. “Control” as used herein is not limited to a single, specific magnetic resonance scanner, but is applicable to a general magnetic resonance scanner. For example, a physician together with a patient can configure the magnetic resonance examination on a mobile telephone during a consultation. The physician can transfer the control data of the magnetic resonance examination to the patient's mobile telephone. The control data are then transferred to the magnetic resonance tomography device during the actual magnetic resonance examination, allowing the magnetic resonance examination to be performed.

In an embodiment of the magnetic resonance tomography system, the portable control device has a visual display for visualizing the control data. This has the advantage that the control data can be checked visually.

In a further embodiment of the magnetic resonance tomography system, the visual display is a touch-sensitive display. This has the advantage that the control data can be edited and changed in a simple manner.

In a further embodiment of the magnetic resonance tomography system, the control device is a smart phone or tablet PC. This has the advantage that the control data can be transmitted via a mobile radio network.

In a further embodiment of the magnetic resonance tomography system, the magnetic resonance scanner is configured to activate a pre-installed function of the magnetic resonance scanner based on the transferred control data. This has the advantage that operation of the magnetic resonance tomography device is simplified.

In a further embodiment of the magnetic resonance tomography system, the first interface is a UMTS interface, a WLAN interface, a GSM interface or an LTE interface. This has the advantage that the data can be transmitted quickly to the control device.

In a further embodiment of the magnetic resonance tomography system, the second interface is a WLAN interface or a Bluetooth interface. This similarly has the advantage that the data can be transmitted quickly to the magnetic resonance tomography device.

In a further embodiment of the magnetic resonance tomography system, the control device has a user interface for entering personal data. This has the advantage that user data can be linked to the control data.

In a further embodiment of the magnetic resonance tomography system, the control device has a user interface for controlling an examination table manually. This has the advantage that operation of the magnetic resonance tomography device is simplified.

In a further embodiment of the magnetic resonance tomography system, the control device has a user interface for selecting different sets of control data. This has the advantage that the magnetic resonance examination can be configured on the control device.

In a further embodiment of the magnetic resonance tomography system, the control device is configured to transmit type information of the magnetic resonance tomography device or software version information via the first wireless data interface. This has the advantage that it is possible to download control data matched to the magnetic resonance tomography device.

According to a second aspect of the invention, the object is achieved by a method for controlling a magnetic resonance tomography device, with the steps of receiving control data from a data network via a first wireless data interface with a portable control device; and transferring the control data from the portable control device to the magnetic resonance tomography device via a second, wireless data interface. The method has the same advantages as the magnetic resonance tomography system.

In an embodiment of the method, the control data are visualized on a visual display. This similarly has the advantage that the control data can be checked visually.

In a further embodiment of the method, the control data are received from the data network as a function of the type of magnetic resonance scanner. This similarly has the advantage that matched control data is transmitted.

In a further embodiment of the method, a pre-installed function of the magnetic resonance scanner is activated based on the transferred control data. This similarly has the advantage that operation is facilitated.

### BRIEF DESCRIPTION OF THE DRAWINGS

FIG. 1 is a schematic illustration of a magnetic resonance tomography system according to the invention.

FIG. 2 is a schematic illustration of a control device according to the invention.

FIG. 3 is a further schematic illustration of the control device according to the invention.

### DESCRIPTION OF THE PREFERRED EMBODIMENTS

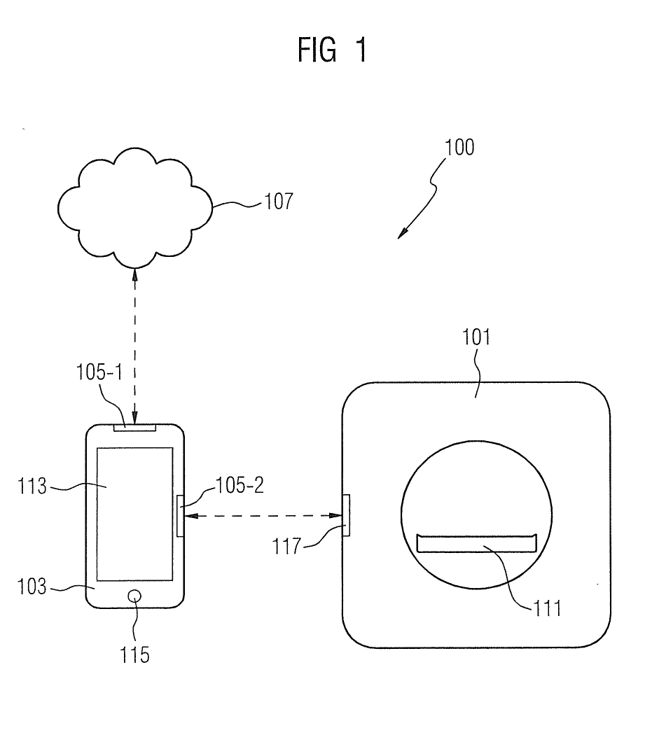

FIG. 1 is a schematic illustration of a magnetic resonance tomography system 100. The magnetic resonance tomography system 100 has a magnetic resonance scanner 101 and a control processor 103, for example a smart phone.

The magnetic resonance scanner 101 is a device for performing an imaging method used in medical diagnostics for representing the structure and function of tissue and organs in the body. It is based physically on the principles of nuclear magnetic resonance (NMR), in particular field gradient NMR, and is therefore also referred to as magnetic resonance tomography.

The control processor 103 has a first, wireless data interface 105-1 for receiving control data for the magnetic resonance scanner 101 from a data network 107 and a second, wireless data interface 105-2 for transferring the control data 109-1, . . . , 109-5 to the magnetic resonance scanner 101. The control processor 103 also has a control button 115 and a visual matrix display 113. The control processor 103 can also has a buffer for storing the received control data. The magnetic resonance scanner 101 also has a data interface 117, via which the magnetic resonance scanner 101 communicates with the data interface 105-2 of the control processor 103.

The control processor 103 allows the downloading and transmitting of control data for the magnetic resonance scanner 101 from a data network 107, for example from a server from the internet. The control data are, for example, data defining an imaging operation (hanging protocols), data relating to clinical protocols (best clinical protocols), user interfaces, data relating to pulse sequences, data for generating and sharing protocols and sequences, post-processing software or software update data. It is also possible for a user to obtain information relating to the magnetic resonance examination. The control processor 103 can also be used to perform clinical experiments or tests.

Located in the interior of the magnetic resonance scanner 101 is a retractable examination table 111. The control processor 103 can have a user interface for retracting and extending the examination table 111 manually, by pushing corresponding buttons or touching the touch-sensitive display 113. The control processor 103 can then be used as a remote control for controlling the examination table 111. The control processor 103 can also have a user interface for entering patient data in order to link the patient data to the control data.

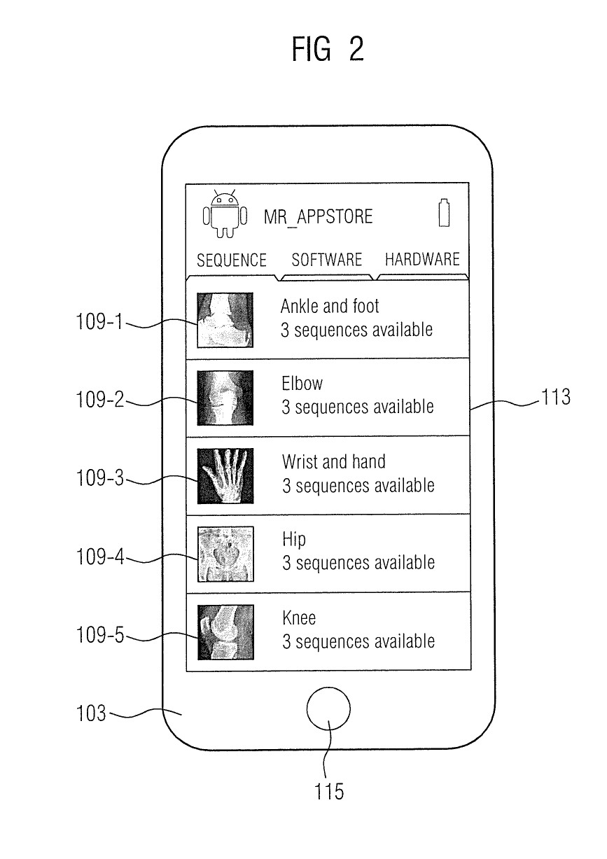

FIG. 2 is a schematic illustration of a control processor 103. The control processor 103 has a touch-sensitive visual display 113 for visualizing the control data 109 1, . . . , 109-5. The control data 109-1, . . . , 109-5 can be selected by a user via a user interface, by touching the relevant point on the display 113. The control data 109-1 represent specific sequences for examining the ankle and foot. The control data 109-2 represent specific sequences for examining the elbow. The control data 109-3 represent specific sequences for examining the wrist and hand. The control data 109-4 is specific sequences for examining the hip. The control data 109-5 represent specific sequences for examining the knee.

The visual display 113 can also show information about the types of new image processing software or new hardware that are available. If updates are available, a window appears on the display 113, in which such updates are described. Price information for downloading the control data 109-1, . . . , 109-5 and installation information can also be displayed before the control data 109-1, . . . , 109-5 is downloaded.

The control data 109-1, . . . , 109-5, for example proven protocols, can be shared between user groups, commented on and evaluated. It can also be bought and sold.

Control data 109-1, . . . , 109-5 can also be provided in the form of keys, which can activate or enable defined functions of the magnetic resonance scanner 101. The magnetic resonance scanner 101 is then provided to the user with a complete software package, with which the basic functions are activated and optional additional functions are blocked. Downloaded keys can be used to activate the blocked additional functions.

After an initial examination has been performed on the patient and diagnostic questions have been clarified by the physician, a specific examination program, for example on the magnetic resonance scanner 101, may be deemed necessary. If the patient has had a stroke for example, the physician may decide that a blood flow and diffusion image should be generated. It may be the case for pre-operative planning that the physician wishes to perform voxel-based morphometry during post-processing.

To this end, the user can use the control processor 103, i.e. the mobile telephone, to download the required keys for enabling the relevant function and the magnetic resonance protocol as control data from a provider from the data network 107. To this end a request is sent to the provider, with which the respective keys are transmitted to the control processor 103. The keys are then sent from the control processor 103 to the magnetic resonance scanner 101.

Downloads can be provided using a limited or unlimited pay per use contract. If a certain magnetic resonance protocol or post-processing tool is required for a certain patient, it can be downloaded by a user from the producer's server.

Generally the control data can be any data that can be used to set or control the magnetic resonance scanner 101, for example data relating to magnetic resonance sequences, post-processing tools or proven examination protocols.

The control data can only be used by the control processor 103 when deemed necessary. This results in a more sparing and efficient use of hardware and software resources.

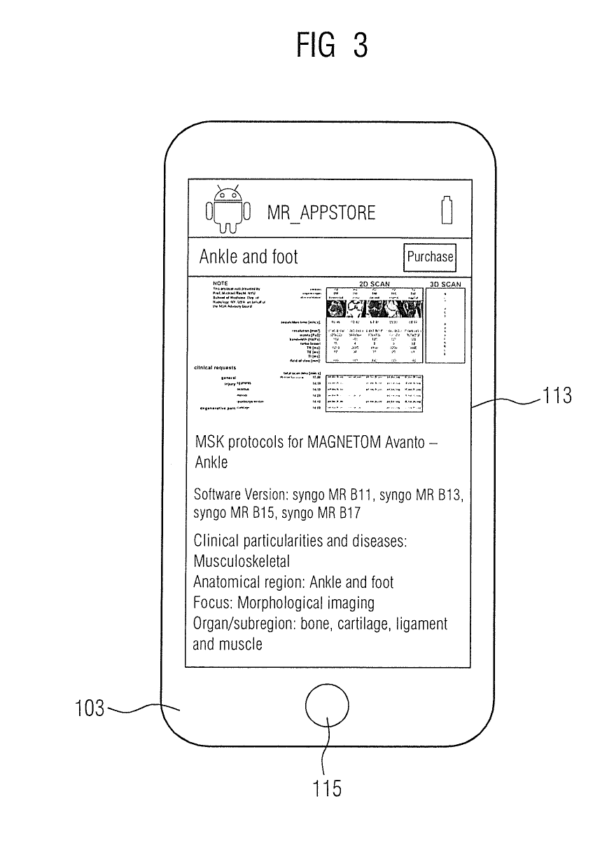

FIG. 3 shows a further schematic illustration of the control processor 103. Displayed on the visual display 113 is information relating to the magnetic resonance examination. The visual display 113 can also be used to display operating instructions or new product information.

The magnetic resonance system 100 is implemented in a technically simple manner. The use of a mobile telephone as a control processor 103 allows new applications in the field of magnetic resonance tomography, with which users are informed about examination conditions.

The magnetic resonance system 100 also allows the use of a smart phone or tablet PC for downloading keys, in order to activate or enable software options for the magnetic resonance scanner 101, for example stored applications.

The user can also obtain services by using standard mobile telephone components, for example instructions and voice commands for installing keys. The services can be billed individually based on the downloaded control data. An automatically learning implementation can be created for user-specific settings and recommendations. The concept of downloading control data to the portable control processor 103 can be extended to other applications.

All the features explained and illustrated in conjunction with individual embodiments of the invention can be provided in the inventive subject matter in different combinations in order to achieve their advantageous effects simultaneously.

Although modifications and changes may be suggested by those skilled in the art, it is the intention of the inventors to embody within the patent warranted hereon all changes and modifications as reasonably and properly come within the scope of their contribution to the art.

We claim as our invention:

1. A magnetic resonance tomography system comprising:
a magnetic resonance tomography apparatus configured to perform a magnetic resonance examination; and
a portable control processor comprising a first wireless data interface configured to receive control data for said magnetic resonance tomography apparatus from a data network, and a second wireless data interface configured to interface with the magnetic resonance tomography apparatus to transfer said control data from said portable control processor to said magnetic resonance tomography apparatus.

2. A magnetic resonance tomography system as claimed in claim 1 wherein said portable control processor comprises a visual display configured to visually present said control data.

3. A magnetic resonance tomography system as claimed in claim 2 wherein said visual display is a touch-sensitive display.

4. A magnetic resonance tomography system as claimed in claim 2 wherein said control processor is a smart phone or tablet PC.

5. A magnetic resonance tomography system as claimed in claim 1 wherein said magnetic resonance tomography apparatus is configured to activate a pre-installed function of the magnetic resonance tomography apparatus based on said control data transferred thereto.

6. A magnetic resonance tomography system as claimed in claim 1 wherein said first interface is selected from the group consisting of a UMTS interface, a WLAN interface, a GSM interface, and an LTE interface.

7. A magnetic resonance tomography system as claimed in claim 1 wherein said second interface is an interface selected from the group consisting of a WLAN interface and a Bluetooth interface.

8. A magnetic resonance tomography system as claimed in claim 1 wherein said control processor comprises a user interface configured to allow entry of personal data into said control processor.

9. A magnetic resonance tomography system as claimed in claim 1 wherein said magnetic resonance tomography apparatus comprises a movable examination table, and wherein said portable control processor comprises a user interface configured to allow manual control of movement of said examination table from said portable control processor.

10. A magnetic resonance tomography system as claimed in claim 1 wherein said portable control processor comprises a user interface configured to allow selection of different sets of said control data.

11. A magnetic resonance tomography system as claimed in claim 1 wherein said portable control processor is configured to transmit, in said control data, type information of said magnetic resonance tomography apparatus or software version information.

12. A method for controlling a magnetic resonance tomography apparatus, comprising:
at a portable control processor, receiving control data from a network via a first wireless data interface of the portable control processor;
establishing communication between a second wireless data interface of said portable control processor and a magnetic resonance tomography apparatus; and
transferring said control data from said portable control processor to said magnetic resonance tomography apparatus via said second wireless data interface.

13. A method as claimed in claim 12 comprising visually presenting said control data at a visual display of said portable control processor.

14. A method as claimed in claim 12 comprising receiving said control data at said portable control processor dependent on a type of said magnetic resonance tomography apparatus.

15. A method as claimed in claim 12 comprising activating a pre-installed function of the magnetic resonance tomography apparatus at the magnetic magnetic resonance tomography apparatus upon transfer of said control data from said portable control processor to said magnetic resonance tomography apparatus.
